(19) United States
(12) Patent Application Publication
(10) Pub. No.: US 2026/0018447 A1
(43) Pub. Date: Jan. 15, 2026

(54) LOAD PORT MOUNTING POSITION ADJUSTMENT MECHANISM

(71) Applicant: Sinfonia Technology Co., Ltd., Tokyo (JP)

(72) Inventors: Tatsuya Miura, Tokyo (JP); Shinpei Kogiso, Tokyo (JP); Yuki Ishihara, Tokyo (JP); Tatsuru Ogawa, Tokyo (JP); Atsushi Suzuki, Tokyo (JP); Yuki Matsumoto, Tokyo (JP)

(73) Assignee: Sinfonia Technology Co., Ltd., Tokyo (JP)

(21) Appl. No.: 18/995,509

(22) PCT Filed: Jun. 30, 2023
(86) PCT No.: PCT/JP2023/024330

§ 371 Date: Jan. 16, 2025

(30) Foreign Application Priority Data
Jul. 19, 2022 (JP) 2022-114694

(51) Int. Cl. H01L 21/68; H01L 21/67

(52) U.S. Cl. CPC H01L 21/68; H01L 21/67196

(57) ABSTRACT

A load port mounting position adjustment mechanism is capable of adjusting a mounting position of a load port on a wall surface of a transfer chamber, and includes: an X-axis adjustment part configured to adjust the position of the load port in a width direction of the wall surface; a Y-axis adjustment part configured to adjust the position of the load port in a thickness direction of the wall surface; and a Z-axis adjustment part configured to adjust the position of the load port in a height direction of the wall surface. A three-axis adjustment mechanism that integrates the X-axis, the Y-axis, and the Z-axis adjustment parts is mounted to the wall surface by using a mounting hole formed in either an upper section or a middle section of the wall surface. This improves the workability of mounting the load port to the wall surface with a high precision.

### TECHNICAL FIELD

The present disclosure relates to a load port mounting position adjustment mechanism that adjusts the position (mounting position) of a load port mounted on a front surface of a substrate transfer device.

### BACKGROUND

For example, in a semiconductor manufacturing process, a wafer (an example of a substrate) is processed in a clean room to improve a yield and a quality. In recent years, a “mini-environment system” has been introduced to further improve the cleanliness of only a local space around a wafer, and a means for transferring and processing the wafer has been adopted. In the mini-environment system, a load port is provided adjacent to a transfer chamber, wherein the load port constitutes a part of a wall surface of a wafer transfer chamber (hereinafter referred to as a transfer chamber) substantially sealed inside a housing and has a function of placing a FOUP (Front-Opening Unified Pod), which is a storage container for storing transfer target objects, such as wafers or the like, in the highly clean internal space, and opening and closing a door of the FOUP while being in close contact with the door of the FOUP.

The operations of mounting the load port to the transfer chamber and adjusting the position of the load port are carried out by placing legs provided at the lower portion of the load port on leg receiving portions having appropriate adjustment bolts such as jack bolts provided near the lower end of the wall surface of the transfer chamber, and then appropriately adjusting the adjustment bolts (see Patent Documents 1 and 2 below).

### PRIOR ART DOCUMENTS

### Patent Documents

Patent Document 1: Japanese Patent No. 5910019

Patent Document 2: Japanese Patent No. 5988076

However, in order for an operator to access the appropriate adjustment bolts such as jack bolts, the operator is forced to crawl into a recessed area near the lower end of the load port and perform an adjustment work in that posture. Thus, there is a problem in that the workability is poor and the mounting work, including a position adjustment process, takes a lot of time.

Furthermore, in the related art, if some height position adjustment bolts continue to be exposed and protruded more downward than the surrounding parts after the load port mounting operation is completed, it is anticipated that when the load port kept alone or mounted to the transfer chamber is moved by a forklift, the forklift's tines would come into contact with or get caught on the lower end of the height position adjustment bolt, causing the load port to tip over. Thus, extreme caution is required when using a forklift or other loading trucks to move the load port.

The present disclosure provides some embodiments of a load port mounting position adjustment mechanism that makes it possible to perform an operation of adjusting the mounting position of a load port with respect to the wall surface of a transfer chamber smoothly in a comfortable posture and also makes it possible to perform a moving operation using a loading truck smoothly.

### SUMMARY

According to one embodiment of the present disclosure, there is provided a load port mounting position adjustment mechanism capable of adjusting a mounting position of a load port on a wall surface of a transfer chamber that defines a substantially closed substrate transfer space therein. The load port mounting position adjustment mechanism according to the present disclosure includes: an X-axis adjustment part configured to adjust the position of the load port in a width direction W (left-right direction) of the wall surface; a Y-axis adjustment part configured to adjust the position of the load port in a thickness direction (front-rear direction) of the wall surface; and a Z-axis adjustment part configured to adjust the position of the load port in a height direction (up-down direction) of the wall surface, wherein a three-axis adjustment mechanism that integrates (unitize) the X-axis adjustment part, the Y-axis adjustment part and the Z-axis adjustment part is mounted to the wall surface by using a mounting hole formed in at least one of an upper section or a middle section of the wall surface.

With such a load port mounting position adjustment mechanism according to the present disclosure, the three-axis adjustment mechanism is mounted to the wall surface using the mounting hole formed in the upper section or the middle section of the wall surface. Therefore, the operator can adjust the mounting position of the load port in the respective directions (left-right, front-rear, and up-down directions) with respect to the wall surface at the position of the upper or middle section of the wall surface using the X-axis adjustment part, the Y-axis adjustment part, and the Z-axis adjustment part, thereby eliminating the need to perform the adjustment operation in an awkward posture as in the related art and shortening the operation time. In particular, the SEMI standard stipulates that the mounting hole is formed in the upper, middle, or lower section of the wall surface. Therefore, by mounting the three-axis adjustment mechanism to the wall surface using the mounting hole, it is not necessary to form a separate dedicated mounting hole, which is advantageous.

Furthermore, with the load port mounting position adjustment mechanism according to the present disclosure, there is no need to arrange a height position adjustment bolt near the lower end of the load port. Therefore, when the load port alone or the entire EFEM including the load port mounted to the transfer chamber is moved by a forklift, there is no possibility that the forklift tines come into contact with or get caught on the height position adjustment bolt, causing it to tip over. This makes it possible to smoothly perform the moving operation using a loading truck such as a forklift or the like, which improves the safety and the workability.

In a configuration of the related art in which an adjustment bolt needs to be appropriately adjusted in a state in which a leg provided at the lower portion of the load port is placed on a leg receiving portion having an appropriate adjustment bolt such as a jack bolt provided near the lower end of the wall surface of a transfer chamber, it is necessary to temporarily tilt the entire load port in order to place the leg provided at the lower portion of the load port on the leg receiving portion. With such a configuration of the related art, it is thought that the operation of lifting and tilting the load port which is becoming larger and heavier as the wafers become larger, becomes more complex, thereby increasing the burden and risk on the operator.

On the other hand, with the load port mounting position adjustment mechanism according to the present disclosure, by placing the above-mentioned three-axis adjustment mechanism on the upper or middle section of the wall surface, no height position adjustment function is required for a leg receiving portion provided near the lower end of the wall surface of the transfer chamber. With this in mind, the load port mounting position adjustment mechanism according to the present disclosure includes a leg provided at the lower end portion of the base frame and the leg receiving portion provided on the lower section of the wall surface to support the leg. The leg receiving portion includes a groove into which the lower end of the leg is fitted and an upward facing surface. A front portion of the upward facing surface is a portion further from the wall surface than the groove with the groove used as a boundary, and is set at a lower position than a rear portion of the upward facing surface, which is a portion closer to the wall surface than the groove. By doing so, it is possible to place the leg provided at the lower portion of the load port on the leg receiving portion without temporarily tilting the entire load port. In other words, when the load port is moved toward the transfer chamber during the operation of mounting the load port to the wall surface of the transfer chamber, the lower end of the leg passes above the upward facing surface of the front portion of the leg receiving portion, fits into the groove, and then abuts the rear portion to ensure that the leg remains fitted in the groove. This eliminates the need to lift the load port, thereby reducing the burden and risk on the operator.

Furthermore, in the load port mounting position adjustment mechanism according to the present disclosure, if a handle having a handle main body arranged at a position spaced apart from the wall surface of the transfer chamber by a predetermined distance is provided and the handle main body is configured to be accessible by the operator at least when mounting the load port to the wall surface, the operator can grasp the handle main body and push the load port toward the wall surface of the transfer chamber, which makes it possible to cope with the increase in the size of the load port.

According to the present disclosure, by integrating and arranging the X-axis adjustment part, the Y-axis adjustment part, and the Z-axis adjustment part at the upper end portion or the vertical center portion of the load port, it is possible to provide a load port mounting position adjustment mechanism that enables an operator to adjust the left-right mounting position, front-rear mounting position, and up-down mounting position of the load port with respect to the wall surface of the transfer chamber in a relatively comfortable posture.

### BRIEF DESCRIPTION OF DRAWINGS

FIG. 1 is a side view schematically showing the relative positional relationship between an EFEM equipped with a load port and its peripheral devices in one embodiment of the present disclosure.

FIG. 2 is a plan view showing a simplified version of the relative positional relationship shown in FIG. 1.

FIG. 3 is a front view showing the load port according to the embodiment with some parts omitted.

FIG. 4 is a rear view of the load port according to the embodiment.

FIG. 5 is a rear view showing the load port according to the embodiment with some parts omitted.

FIGS. 6A and 6B are explanatory diagrams of the operation of a connection switching mechanism according to the embodiment.

FIGS. 7A and 7B are views showing a connection switching mechanism in the related art, which corresponds to FIGS. 6A and 6B.

FIG. 8 is a view seen in the direction of the arrow A in FIG. 5.

FIG. 9 is a sectional view taken along line B-B in FIG. 5.

FIG. 10 is a view showing a state in which a mapper is positioned at a mapping position, which corresponds to FIG. 9.

FIG. 11 is a front view of a load port equipped with a three-axis adjustment mechanism according to the embodiment.

FIG. 12 is a view of region C in FIG. 11 as seen at a predetermined angle.

FIG. 13 is an enlarged view of region C in FIG. 11.

FIG. 14 is a sectional view taken along line E-E in FIG. 13.

FIG. 15 is a sectional view taken along line F-F in FIG. 13.

FIG. 16 is a front view of the load port according to the embodiment with some parts omitted.

FIG. 17 is an enlarged view of region Q in FIG. 16.

FIG. 18 is a sectional view taken along line a-a in FIG. 16.

FIG. 19 is a view of region R in FIG. 16 seen at a predetermined angle.

FIG. 20 is a view of region S in FIG. 16 seen at a predetermined angle.

### DETAILED DESCRIPTION

An embodiment of the present disclosure will now be described with reference to the drawings. A load port mounting position adjustment mechanism T according to this embodiment is a mechanism for adjusting the mounting position of a load port 1 with respect to a wall surface 2F (front wall surface) of a transfer chamber 2 when mounting the load port 1 to the wall surface 2F (front wall surface) of the transfer chamber 2.

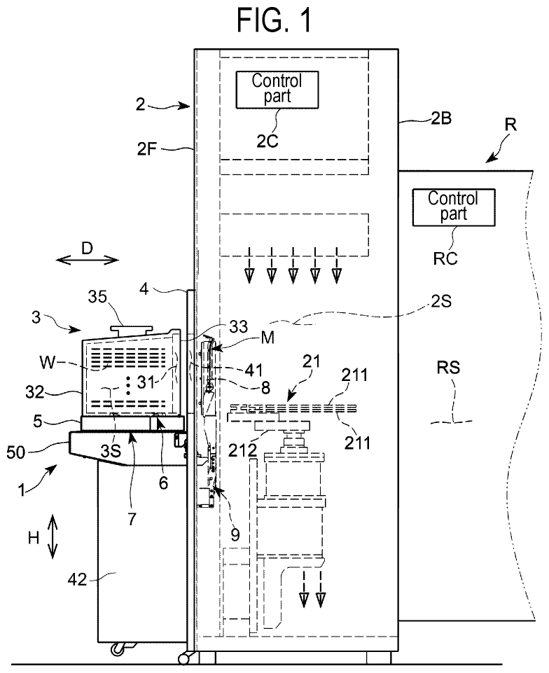

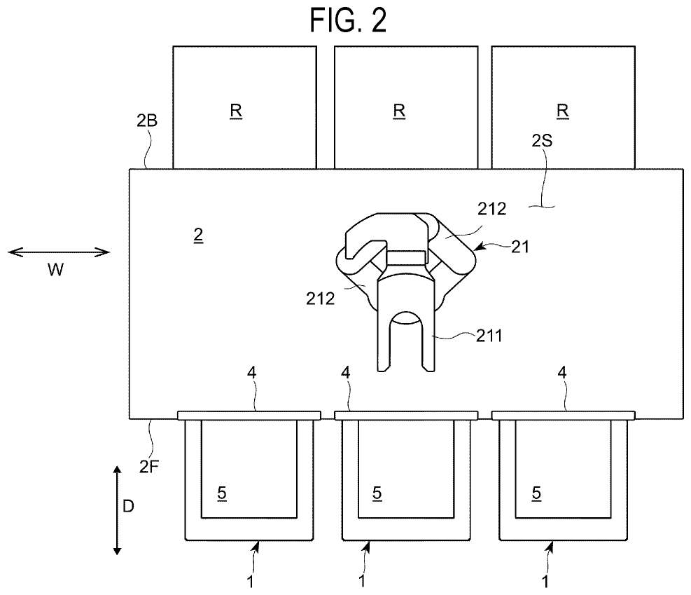

The load port 1 is used, for example, in a semiconductor manufacturing process. As shown in FIGS. 1 and 2, the load port 1 constitutes a part of a wall surface 2F (front wall surface) of a transfer chamber 2 in a clean room and is used to load and unload transfer target objects such as wafers W between the transfer chamber 2 and a transfer container 3 such as a FOUP or the like. The load port 1 constitutes a part of an EFEM (Equipment Front End Module) together with the transfer chamber 2, and functions as an interface between the transfer container 3 and the transfer chamber 2. In this embodiment, in a front-rear direction D (see FIG. 1, etc.) in which the transfer container 3, the load port 1, and the transfer chamber 2 are arranged in the named order, the transfer container side is defined as a front side, and the transfer chamber side is defined as a rear side.

As schematically shown in FIG. 1, the transfer container 3 may be a FOUP 3 that includes a FOUP body 32 whose internal space 3S is capable of being opened only to the rear side via a loading/unloading port 31, and a FOUP door 33 capable of opening and closing the loading/unloading port 31. The FOUP 3 is a known container provided with multiple slots therein, configured to accommodate wafers W as transfer target objects in the respective slots, and configured to allow the wafers W to be loaded and unloaded via the loading/unloading port 31. A flange portion 35 to be gripped by a device (e.g., an overhead transport (OHT)) that automatically transfers the transfer container 3 is provided on an upper surface of the FOUP body 32.

As shown in FIG. 1 and the like, the load port 1 includes a plate-shaped base frame 4 having an opening 41 formed to open an internal space 2S of a transfer chamber 2, a mounting table 5 provided in a substantially horizontal posture to protrude to the front side from the base frame 4, a seating holding mechanism 6 configured to hold a FOUP 3 transferred from the outside on the mounting table 5, a towing mechanism 7 configured to move the FOUP 3 on the mounting table 5 in the front-rear direction D between a seating position and a delivery position of the transfer target object, a load port door 8 configured to open and close the opening 41 of the base frame 4, and a door opening/closing mechanism 9 configured to open the opening 41 of the base frame 4 by moving the load port door 8 to a door opening position retracted toward the transfer chamber 2.

The base frame 4 is arranged in an upright posture and has a generally rectangular plate shape having an opening 41 large enough to communicate with the loading/unloading port of the FOUP 3 mounted on the mounting table 5. The opening 41 of the base frame 4 is shown schematically in FIG. 1. In the load port 1 of this embodiment, the base frame 4 constitutes a part of the wall surface 2F (front wall surface) of the transfer chamber 2. The lower end of the base frame 4 is provided with legs 42 having casters and installation leg portions.

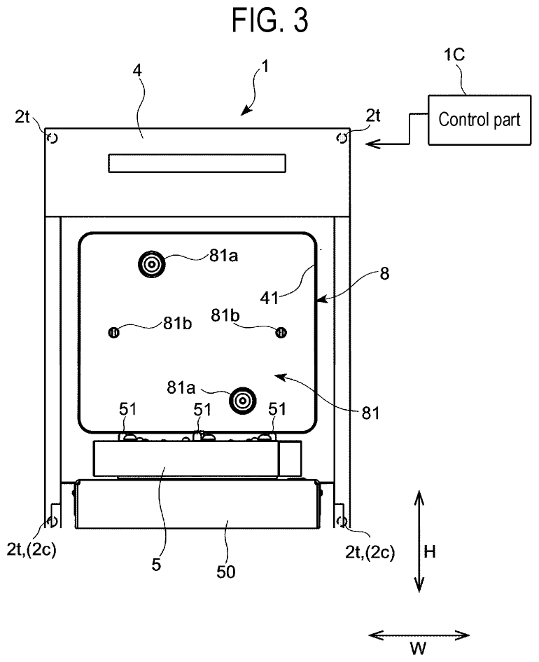

The mounting table 5 is provided on the upper portion of a horizontal base 50 (support base) disposed in a substantially horizontal posture at a position slightly above the vertical center of the base frame 4, and is capable of mounting the FOUP 3 with the FOUP body 32 facing the base frame 4. As shown in FIG. 3, the mounting table 5 is provided with a plurality of protrusions 51 that protrude upward. The FOUP 3 is positioned on the mounting table 5 by bringing these protrusions 51 into engagement with holes (not shown) formed on the bottom surface of the FOUP 3.

The seating holding mechanism 6 holds the FOUP 3 on the mounting table 5 by establishing a locked state in which locking claws (not shown) provided on the mounting table 5 are hooked and fixed onto locked portions (not shown) provided on the bottom surface of the FOUP 3. Furthermore, in the load port 1 of this embodiment, the FOUP 3 can be made separable from the mounting table 5 by unlocking the locking claws from the locked portions.

The towing mechanism 7 moves the FOUP 3 on the mounting table 5 in the front-rear direction D between a seating position where the FOUP body 32 is spaced apart from the load port door 8 by a predetermined distance and a delivery position of the transfer target object where the FOUP body 32 is brought into close contact with the load port door 8. The towing mechanism 7 is configured by using slide rails (not shown) and the like that move the mounting table 5 forward and rearward. The seating holding mechanism 6 and the towing mechanism 7 may also be regarded as mechanisms included in the mounting table 5.

In FIG. 1, as a state in which the FOUP 3 is mounted on the mounting table 5, a state in which the bottom surface of the FOUP 3 is in contact with the upper surface of the mounting table 5 is schematically shown. However, in reality, since the FOUP 3 is supported by the plurality of protrusions 51 protruding upward from the upper surface of the mounting table 5 while the plurality of protrusions 51 is engaged with bottom-closed holes formed on the bottom surface of the FOUP 3, the upper surface of the mounting table 5 and the bottom surface of the FOUP 3 do not come into contact with each other, and a predetermined gap is formed between the upper surface of the mounting table 5 and the bottom surface of the FOUP 3.

The load port door 8 is movable between a fully closed position (see FIG. 1) in which the opening 41 of the base frame 4 is sealed, a door open position in which the load port door 8 is retreated toward the transfer chamber 2 from the fully closed position, and a fully open position in which an opening space of the opening 41 is fully opened rearward. As shown in FIG. 3, the load port door 8 includes an attraction engagement part 81 having an attraction portion 81a capable of attracting the FOUP door 33 and an engagement claw 81b capable of engaging with an engagement hole (latch hole) of the FOUP door 33. The load port door 8 is configured to be movable together with the FOUP door 33 between the fully closed position, the door open position, and the fully open position while maintaining engagement with the FOUP door 33 by the attraction engagement part 81. In this embodiment, the postures of the load port door 8 located in the fully closed position and the door open position are set to the same posture. The movement path of the load port door 8 between the fully open position and the fully closed position includes a path (horizontal path) through which the load port door 8 in the fully closed position is moved toward the transfer chamber 2 to the door open position while maintaining its height position, and a path (vertical path) through which the load port door 8 in the door open position is moved downward to the fully open position while maintaining its front-rear position. The FOUP door 33 held by the load port door 8 located at the door open position is positioned together with the load port door 8 at a position rearward of the base frame 4 (at a position completely spaced apart from the FOUP body 32 and located in the internal space 2S of the transfer chamber 2) so that the load port door 8 located at the door open position can move both in the vertical direction and the horizontal direction.

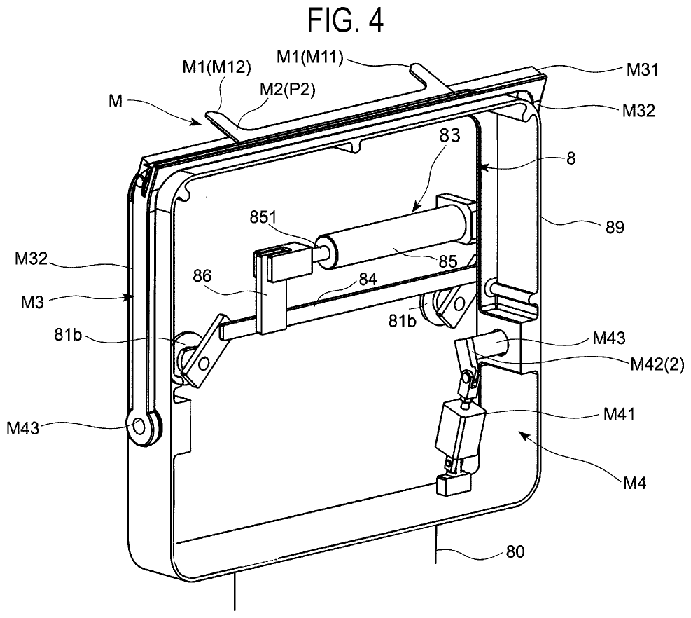

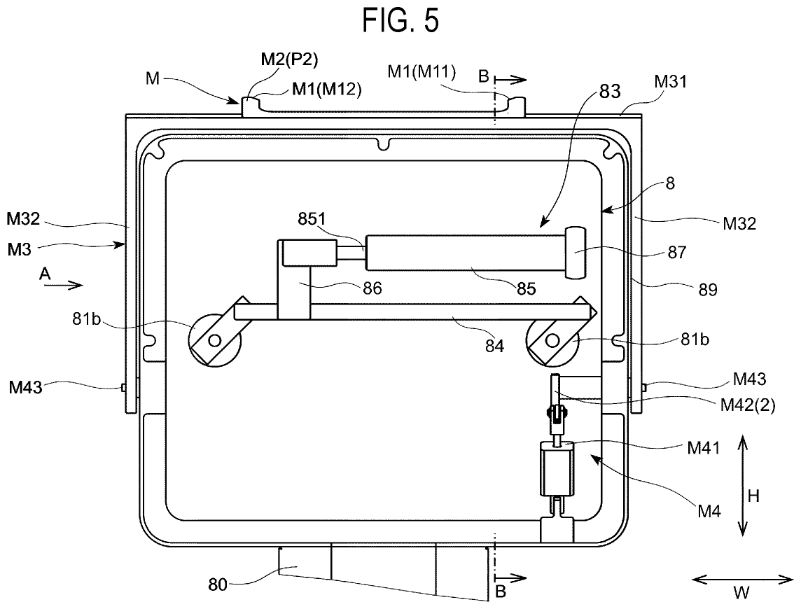

Such movement of the load port door 8 is implemented by the door opening/closing mechanism 9 provided on the load port 1. The door opening/closing mechanism 9 moves the load port door 8 to the door open position or the fully open position, thereby allowing the internal space 3S of the FOUP 3 to communicate with the transfer chamber 2 via the opening 41 of the base frame 4 kept in an open state. The door opening/closing mechanism 9 is configured by, for example, a movable block (not shown) for supporting a support frame 80 (see FIGS. 4 and 5) that supports the load port door 8 so that the support frame 80 can move in the front-rear direction D, and a slide rail (not shown) for supporting the movable block so that the movable block can move in the vertical direction H. The door opening/closing mechanism 9 moves the load port door 8 in the front-rear direction D and the up-down direction H by operating a drive source (not shown) such as an actuator or the like. A configuration in which an actuator for front-rear movement and an actuator for up-down movement may be separately provided. However, in terms of reducing the number of parts, the configuration in which the load port door 8 is moved in the front-rear direction and the up-down direction by using the common actuator as the drive source is superior.

As shown in FIGS. 4 and 5, the load port door 8 according to this embodiment includes a connection switching mechanism 83 for operating the engagement claw 81b of the attraction engagement part 81 to release the engagement state (latched state) between the FOUP door 33 and the FOUP body 32 to establish a state (unlatched state) in which the FOUP door 33 can be removed from the FOUP body 32. The connection switching mechanism 83 is a mechanism that rotates the engagement claw 81b (latch key) engageable with an engagement hole (latch hole) (not shown) provided on the FOUP door 33 within a predetermined angle range. In this embodiment, a connection switching mechanism 83 includes a link bar 84 for connecting a pair of engagement claws 81b provided on the left and right sides to each other, and a cylinder 85 for moving the link bar 84 in the left-right width direction W in response to the advance-retract movement of a cylinder rod 851, and rotates the pair of left and right engagement claws 81b in a synchronized manner in response to the advance-retract movement of the cylinder 85. FIGS. 4 and 5 are views in which a part of the door cover 89 is removed to make the inside visible.

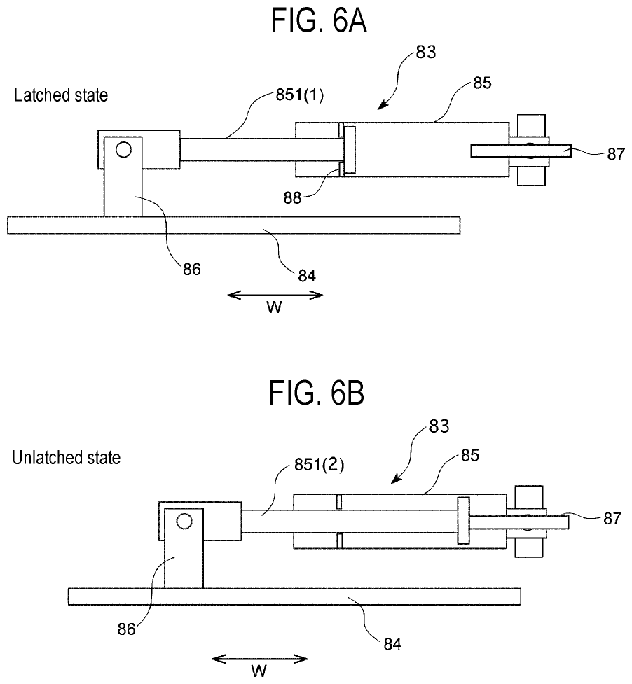

As schematically shown in FIGS. 6A and 6B, in a state in which the engagement claw 81b is engaged with the engagement hole of the FOUP door 33, the cylinder 85 is operated to move a piston rod 851 from a first stroke position (1) to a second stroke position (2).

Therefore, the engagement claw 81b rotates while being engaged with the engagement hole.

As a result, it is possible to establish a state (unlatched state) in which the FOUP door 33 can be removed from the FOUP body 32 (see FIG. 6B). Conversely, when the cylinder 85 is operated to move the piston rod 851 from the second stroke position (2) to the first stroke position (1) in a state in which the engagement claw 81b is engaged with the engagement hole of the FOUP door 33, the engagement claw 81b rotates while being engaged with the engagement hole. As a result, it is possible to establish a state (latched state) in which the FOUP door 33 cannot be removed from the FOUP body 32 (see FIG. 6A).

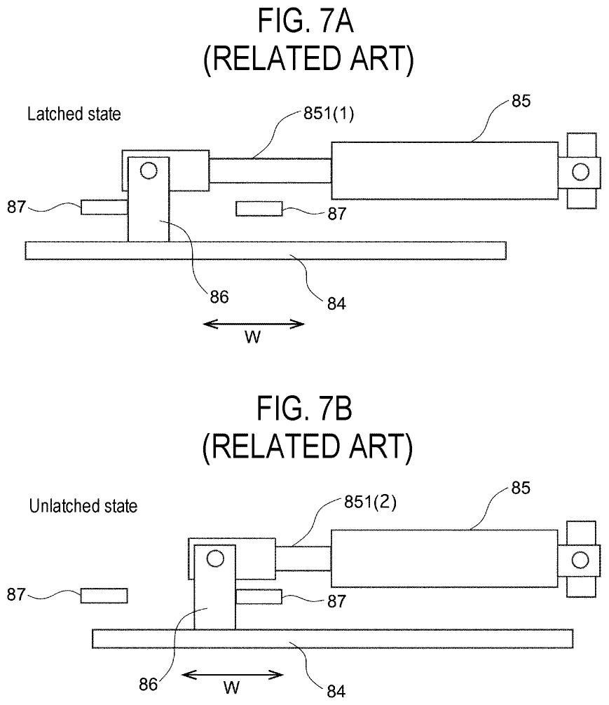

In order to reliably open and close the FOUP door 33 by the load port door 8, it is necessary to reliably insert the engagement claw 81b into the engagement hole of the FOUP door 33 to allow them into engagement with each other, and to rotate the engagement claw 81b in the engaged state. In the related art, as schematically shown in FIGS. 7A and 7B, a configuration in which a cylinder bracket 86 provided at a tip end portion of a piston rod 851 of a cylinder 85 is advanced and retreated in the width direction W together with the piston rod 851 so that a link bar 84 connected to the cylinder bracket 86 is advanced and retreated in the width direction W together with the piston rod 851 is adopted as a configuration for precisely adjusting the rotation angle of the engagement claw 81b. Also adopted is a configuration in which a stopper bolt 87 for determining the distance of forward and backward movement of the cylinder bracket 842 is provided on the load port door 8 and in which, when the cylinder bracket 86 comes into contact with the stopper bolt 87, the advance and retreat movement of the piston rod 851 is stopped to stop the rotation of the engagement claw 81b linked to the advance and retreat movement of the piston rod 851, thereby determining the rotation angle of the engagement claw 81b. FIGS. 7A and 7B show a latched state and an unlatched state, respectively.

In such a configuration of the related art, there is a possibility that dust may be generated by the contact between the stopper bolt 841 and the cylinder bracket 842 and may flow into the transfer chamber 2.

Therefore, in this embodiment, as shown in FIGS. 6A and 6B, a stopper bolt 87 is provided inside the cylinder 85 in which high airtightness is maintained by an appropriate seal structure. As shown in FIG. 6B, the base end (proximal end) of the piston rod 851 comes into contact with the stopper bolt 87 to stop the advance and retreat movement of the piston rod 851 (specifically, the movement in the retreat direction), and the rotation of the engagement claw 81b linked to the advance and retreat movement of the piston rod 851 is stopped, thereby determining the rotation angle of the engagement claw 81b. In particular, in this embodiment, an adjustment bolt is used as the stopper bolt 87, and a tip end position of the adjustment bolt inside the cylinder 85 (the position where it contacts the piston rod 851) is adjustable. In addition, by providing a shock absorbing material 88 (cushion) with which the base end of the piston rod 851 comes into contact at a predetermined position on a tip end side inside the cylinder 85, it is possible to restrict the advance movement of the piston rod 851. Further, the shock absorbing material 88 (cushion) may be provided at a predetermined position on the stopper bolt 87 to restrict the advance movement of the piston rod 851.

According to this configuration, although contact between parts occurs inside the cylinder 85 when the cylinder 85 is driven, the inside of the cylinder 85 is maintained at a high level of airtightness by an appropriate sealing structure, so that dust generated inside the cylinder 85 is kept inside the cylinder 85. As a result, it is possible to prevent or suppress a situation in which dust generated inside the cylinder 85 is released to the outside of the cylinder 85. Moreover, compared to the configuration of the related art, there is no need to provide a separate dedicated stopper bolt outside the cylinder 85, which can contribute to simplifying the configuration and reducing the number of parts, thereby reducing costs.

In addition, the load port according to this embodiment includes a mapping mechanism M which maps information relating to the mounting state of the wafers W, including the presence or absence of the wafer W, in each slot 34 of the FOUP 3 located at the transfer position when the opening 41 of the base frame 4 is opened by the door opening/closing mechanism 9.

As shown in FIGS. 1, 4, 5 and 8, the mapping mechanism M includes a mapper M2 having, at its tip end portion, a mapping sensor M1 (transmitter M11 and receiver M12) that can detect the presence or absence of transfer target objects W stored in multiple stages in the height direction H by multi-stage slots provided in the FOUP 3, and a mapping arm M3 (mapping movement part) that supports the mapper M2. The mapping mechanism M is capable of detecting the presence or absence and storage posture of the transfer target objects W in the FOUP 3.

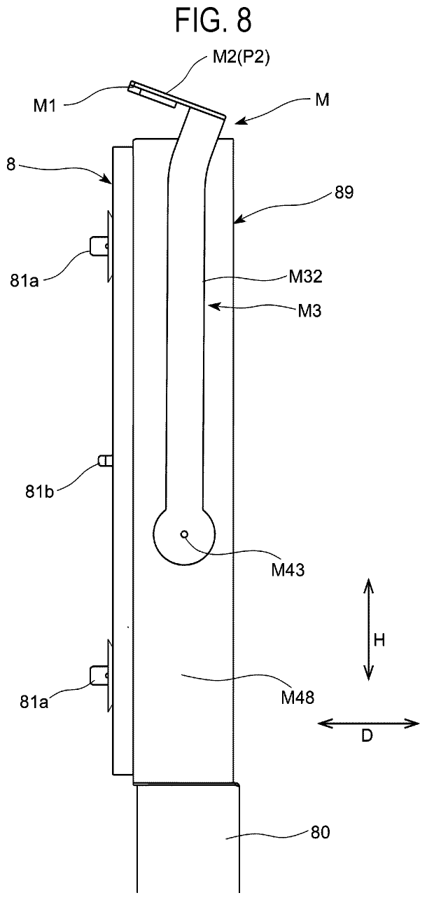

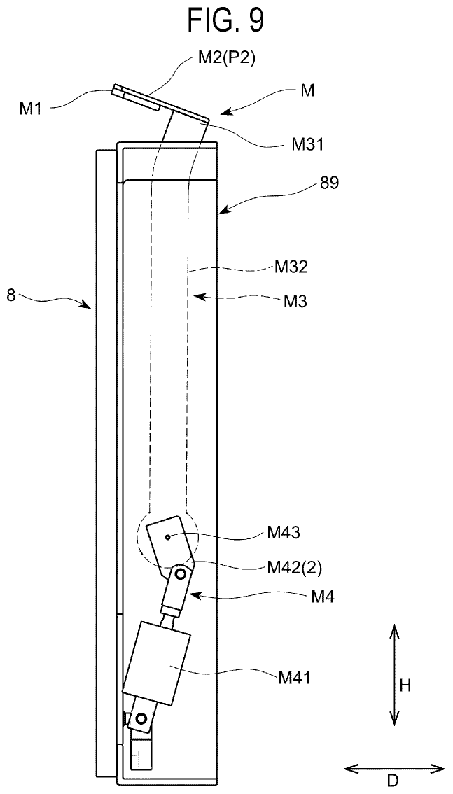

As shown in FIGS. 8 and 9 (which are views seen in the direction of an arrow A in FIG. 5 and a sectional view taken along line B-B in FIG. 5, respectively), mappers M2 are arranged in a pair on the left and right sides and spaced apart by a predetermined distance in the width direction W in such a form that they protrude forward from a predetermined location of the mapping arm M3. The mappers M2 have the mapping sensors M1 attached to their tip end portions. Hatching (parallel oblique lines) indicating a cut surface is omitted in FIGS. 8 and 9. The mapping sensor MI is composed of the transmitter M11 (light emitting sensor) that emits a beam (linear light) as a signal, and the receiver M12 (light receiving sensor) that receives the signal emitted from the transmitter M11. The mapping sensor M1 may also be composed of a transmitter and a reflection part that reflects the linear light emitted from the transmitter toward the transmitter. In this case, the transmitter also functions as a receiver. In order to prevent the mapping sensor M1 (M11 and M12), whose optical axis is oriented horizontally to the left and right, from interfering with the transfer target object W that is to be detected during the mapping process, the left and right span between the mapping sensors M1 (M11 and M12) is set to an appropriate value according to the plan-view dimensions of the transfer target object W.

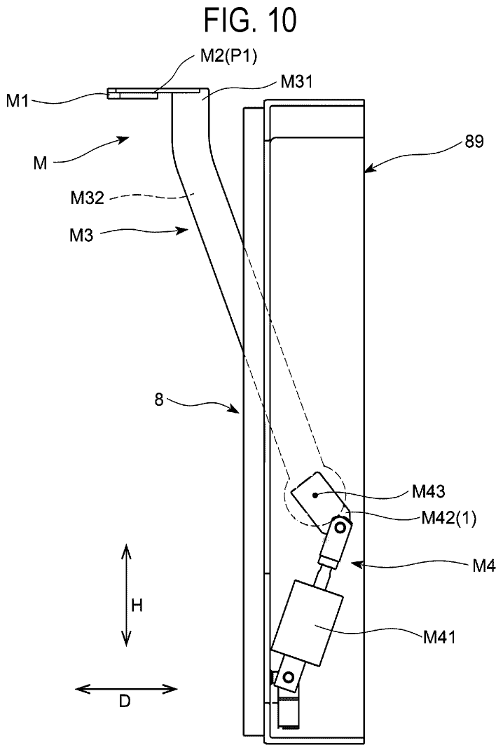

The mapping arm M3 moves the position of the mapper M2 in the front-rear direction D between a position shown in FIG. 10 (i.e., a mapping position (P1) where the mapping sensor M1 can detect that the wafers W are accommodated in the FOUP 3 via the opening 41 in the open state) and a position shown in FIGS. 8 and 9 (i.e., a wafer mapping impossible position (P2) where the mapping sensor M1 cannot detect that the wafers W are accommodated in the FOUP 3). FIG. 10 is a view corresponding to FIG. 9 and showing a state in which the mapper M2 is positioned at the mapping position (P1).

As shown in FIGS. 3 and 4, the mapping arm M3 of this embodiment is shaped like a downward U-shape having an upper frame portion M31 and a pair of left and right side frame portions M32 extending downward from both ends of the upper frame portion M31, either integrally or as a single unit. The mapping arm M3 rotates within a predetermined angle range around the lower end portion of each side frame portion M32 as a rotation center axis to move the position of the mapper M2 between the mapping position (P1) and the wafer mapping impossible position (P2).

In particular, in this embodiment, the lower end portion of each side frame portion M32 is rotatably attached to the side surface of a door cover 89 that covers peripheral parts of the load port door 8 from the transfer chamber 2. In this regard, the mapping mechanism M according to this embodiment includes a tilting mechanism M4 that tilts the entire mapping arm M3 about a pivot point at the mounting portion between the mapping arm M3 and the door cover 89. As shown in FIGS. 9 and 10, the tilting mechanism M4 includes a mapping arm driving cylinder M41, a mapping arm driving crank M42 having one end portion (lower end portion) connected to a tip end portion of the mapping arm driving cylinder M41 (tip end portion of the cylinder rod), and a mapping arm pivot shaft portion M43 (corresponding to the pivot point) connected to the other end portion (upper end portion) of the mapping arm driving crank M42. In this embodiment, the mapping arm driving cylinder M41 and the mapping arm driving crank M42 are disposed in the internal space of the door cover 89. Furthermore, most of the mapping arm pivot shaft portion M43, except for a predetermined region on one end side fixed to the lower end of the mapping arm M3 (the lower end of the side frame M32), is disposed in the internal space of the door cover 89. The mapping arm pivot shaft portion M43 is disposed in an orientation in which its axial direction, which coincides with the longitudinal direction, extends in the width direction W of the load port 1. The lower end portion of the mapping arm M3 (the lower end of the side frame M32) is fixed to one end portion of the mapping arm pivot shaft portion M43 so as to be integrally rotatable, and the mapping arm drive crank M42 is fixed to the other end portion of the mapping arm pivot shaft portion M43 so as to be integrally rotatable. In this embodiment, the mounting position of the mapping arm pivot shaft portion M43 is set to a position slightly lower than the center position in the height direction of the side frame M32 (a position close to the center in the height direction of the load port door 8) (see FIG. 5, etc.).

According to such a tilting mechanism M4 (mapping arm driving mechanism), the mapping arm drive crank M42 moves between the first position (1) and the second position (2) in conjunction with the advance and retreat movement of the mapping arm driving cylinder M41. As shown in FIG. 10, when the mapping arm driving crank M42 is in the first position (1), the mapper M2 can be located at the mapping position (P1). On the other hand, as shown in FIG. 9, when the mapping arm driving cylinder M41 is operated to move the mapping arm driving crank M42 from the first position (1) to the second position (2), the mapping arm pivot shaft portion M43 rotates in conjunction with the movement of the mapping arm driving crank M42, and the mapping arm M3 tilts about the mapping arm pivot shaft portion M43 by an amount corresponding to the rotation angle, so that the mapper M2 can be switched from the mapping position (P1) to the wafer mapping impossible position (P2).

In this embodiment, a first position detection sensor (not shown) for detecting that the mapping arm drive crank M42 is in the first position (1) and a second position detection sensor (not shown) for detecting that the mapping arm drive crank M42 is in the second position (2) are provided. The driving of the mapping arm drive cylinder M41 and the tilting of the mapping arm M3 by the tilting mechanism M4 are controlled based on the detection signals of the first position detection sensor and the second position detection sensor, so that the mapper M2 can be accurately positioned at the mapping position (P1) and the wafer mapping impossible position (P2). In addition, a counterweight (not shown) is provided below the lower end of each side frame part M32 to stabilize the tilting operation of the mapping arm M3 by the tilting mechanism M4. The mapping arm M3 according to this embodiment integrally moves with the door cover 89 in the front-rear and up-down directions, and moves by the tilting mechanism M4 independently of the door opening/closing mechanism 9.

The internal space of the door cover 89 is kept sealed. Therefore, even if particles are generated at the contact portion between the mapping arm driving cylinder M41 and the mapping arm driving crank M42 or at the contact portion between the mapping arm driving crank M42 and the mapping arm pivot shaft portion M43 during the advance and retreat movement of the mapping arm driving cylinder M41, the particles can be confined in the internal space of the door cover 89. As a result, it is possible to prevent or suppress a situation in which the particles are discharged from the internal space of the door cover 89 to the internal space 2S of the transfer chamber 2. In the related art, the rotation center axis of the mapping arm is set at a position lower than the door cover 89, for example, at a predetermined position on the support frame 80 supporting the load port door 8, and the tilting mechanism is also arranged around it. Therefore, there is a possibility that particles generated at the contact portion between the mapping arm driving cylinder and the mapping arm driving crank or at the contact portion between the mapping arm driving crank and the mapping arm pivot shaft portion are discharged into the internal space of the transfer chamber or flew up toward the internal space of the transfer chamber. On the other hand, according to the configuration of this embodiment in which the tilting mechanism M4 tilts and drives the mapping arm M3, it is possible to solve such problems of the related art.

Furthermore, according to the configuration of this embodiment in which the mapping arm M3 is tilted and driven by the tilting mechanism M4, compared to the configuration of the related art in which the center rotation axis of the mapping arm is set at a position lower than the door cover 89, for example at a predetermined position on the support frame 80 that supports the load port door 8, the arm length of the mapping arm M3 (the length from the center rotation axis M43 of the mapping arm M3 to the upper frame portion M31, which is the upper end of the mapping arm M3) is shortened. Therefore, vibration during the operation of the mapping arm M3 can be suppressed more effectively than in the configuration of the related art, thereby contributing to the improvement of mapping accuracy.

The load port 1 according to this embodiment may include a bottom purge part provided on the mounting table 5 and capable of injecting an environmental gas (also called a purge gas) (a nitrogen gas or a dry air is mainly used in this embodiment), which is an appropriately selected gas such as a nitrogen gas, an inert gas or a dry air, into the FOUP 3 from the bottom surface side of the FOUP 3 and replacing the gas atmosphere in the FOUP 3 with the environmental gas. The bottom purge part mainly includes a plurality of nozzles (not shown) provided at predetermined positions on the mounting table 5, and the plurality of nozzles functions as bottom purge injection nozzles that inject a predetermined environmental gas and bottom purge discharge nozzles that discharge the gas atmosphere in the FOUP 3. The plurality of nozzles can be connected in a state of being fitted into an injection port (not shown) and a discharge port (not shown) provided at the bottom of the FOUP 3. Purge processing can be performed by supplying the environmental gas from the bottom purge injection nozzles into the internal space 3S of the FOUP 3 through the injection port, and discharging the gas atmosphere in the internal space 3S of the FOUP 3 from the bottom purge discharge nozzles through the discharge port (the gas atmosphere is an air or a low-cleanliness environmental gas other than an air for a predetermined time from the start of the purge processing, and is a high-cleanliness environmental gas filled in the internal space 3S of the FOUP 3 after a predetermined time has elapsed).

Such a load port 1 constitutes an EFEM together with the transfer chamber 2 equipped with a transfer robot 21 therein. In this embodiment, as shown in FIG. 2, a plurality of load ports 1 (e.g., three load ports) is arranged side by side on the front surface (front wall surface) 2F of the transfer chamber 2. The operation of the EFEM is controlled by a controller of the load port 1 (control part 1C shown in FIG. 2) and a controller of the entire EFEM (control part C shown in FIG. 1).

In the internal space 2S of the transfer chamber 2, there is provided a transfer robot 21 capable of transferring a transfer target object such as a wafer W between the FOUP 3 on the load port 1 and the processing chamber R. As shown in FIGS. 1 and 2, the transfer robot 21 includes an arm 212 configured to connect, for example, a plurality of link elements to each other so as to be horizontally rotatable and provided with a transfer target object gripping part 211 (hand) at a tip end portion of the arm 212, and a traveling unit configured to rotatably support an arm base constituting the base end of the arm 212 and configured to travel in the width direction W of the transfer chamber 2 (the parallel direction of the load port 1). The transfer robot 21 has a link structure (multi-joint structure) whose shape changes between a folded state in which the arm length is at its minimum and an extended state in which the arm length is longer than in the folded state. A transfer robot 21 in which a plurality of hands 211, which is individually controllable, is provided in multiple stages in the height direction at the tip end portion of the arm 212 may be used.

The transfer chamber 2 is configured so that the internal space 2S is substantially sealed by connecting the load port 1 and the processing chamber R. As shown in FIG. 1, a downflow, which is an airflow from above to below, is formed in the internal space 2S of the transfer chamber 2. Therefore, even if particles that contaminate the surface of the wafer W are present in the internal space 2S of the transfer chamber 2, the particles can be pushed downward by the downflow, which makes it possible to suppress the adhesion of the particles to the surface of the wafer W during transfer. In FIG. 1, the flow of a gas in the transfer chamber 2 in which the downflow is formed is schematically indicated by arrows. It is also possible to form an EFEM in which appropriate stations such as a buffer station and an aligner are arranged on the side of the transfer chamber 2 or in the internal space 2S of the transfer chamber 2.

In this embodiment, a plurality of processing chambers R (semiconductor processing apparatuses) (three processing chambers in the illustrated example) is arranged side by side in the width direction W on a wall surface 2B (rear wall surface) of the transfer chamber 2 that faces a wall surface 2F (front wall surface) on which the load port 1 is arranged. The respective processing chambers R are configured to perform different appropriate processes. Examples of the processes performed in an intermediate process or later process of a semiconductor manufacturing process include a back-lapping process, a wafer stacking process, and a dicing process. The operation of the processing chamber R is controlled by a controller (control part RC shown in FIG. 1) of the processing chamber R. In this regard, the controller (control part RC) of the entire processing chamber R and the controller (control part C) of the entire EFEM are higher-level controllers of the control part 1C of the load port 1.

The internal space RS of each processing chamber R, the internal space 2S of the transfer chamber 2, and the internal space 3S of the FOUP 3 placed on each load port 1 are maintained at a high level of cleanliness. On the other hand, the space in which the load port 1 is located, in other words, the outside of the processing chamber and the outside of the EFEM, has a relatively low level of cleanliness. FIGS. 1 and 2 are views schematically showing the relative positional relationship between the load port 1 and the transfer chamber 2, and the relative positional relationship between the EFEM provided with the load port 1 and the transfer chamber 2, and the processing chamber R.

The load port mounting position adjustment mechanism T according to this embodiment is a mechanism for adjusting the mounting position of the load port 1 with respect to the wall surface 2F of the transfer chamber 2 when the load port 1 is placed and mounted to the wall surface (front wall surface 2F) of the transfer chamber 2.

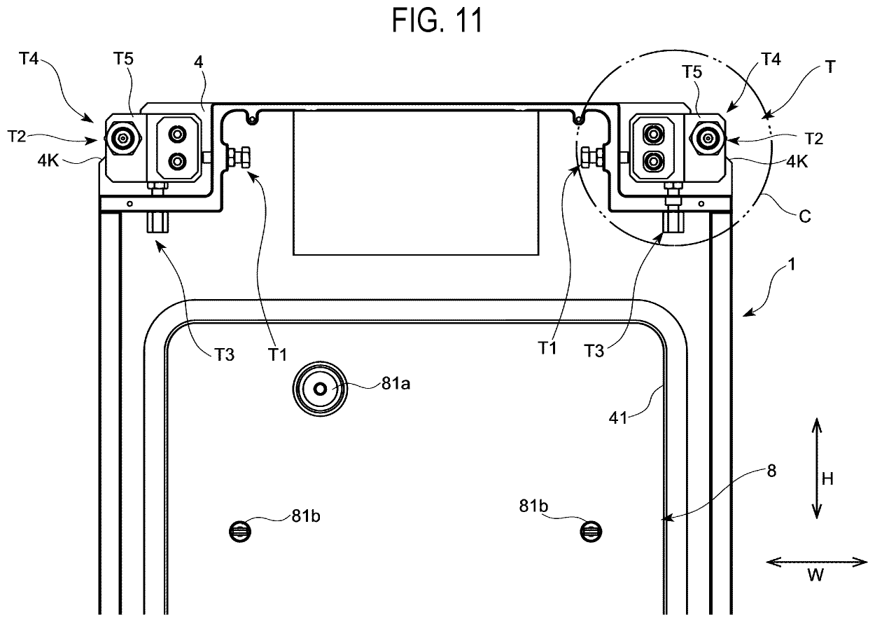

As shown in FIG. 11, the load port mounting position adjustment mechanism T includes an X-axis adjustment part T1 configured to adjust the position of the load port 1 in the width direction W (left-right direction) with respect to the wall surface (front wall surface 2F) of the transfer chamber 2, a Y-axis adjustment part T2 configured to adjust the position (tilt position) of the load port 1 in the thickness direction D (front-rear direction or depth direction) with respect to the wall surface (front wall surface 2F) of the transfer chamber 2, and a Z-axis adjustment part T3 configured to adjust the position of the load port 1 in the height direction H (up-down direction) with respect to the wall surface (front wall surface 2F) of the transfer chamber 2. These adjustment parts in the three axes directions (the X-axis adjustment part T1, the Y-axis adjustment part T2, and the Z-axis adjustment part T3) are combined into a three-axis adjustment mechanism T4 which is located at an upper corner portion of the base frame 4.

The load port mounting position adjustment mechanism T includes a load port guide part T5 that can be placed (mounted) on an upper corner of the base frame 4, and includes an X-axis movable body T11 that can advance and retreat in the width direction W with respect to the load port guide part T5, a Y-axis movable body T21 that can advance and retreat in the front-rear direction D with respect to the load port guide part T5, and a Z-axis movable body T31 that can advance and retreat in the height direction H with respect to the load port guide part T5.

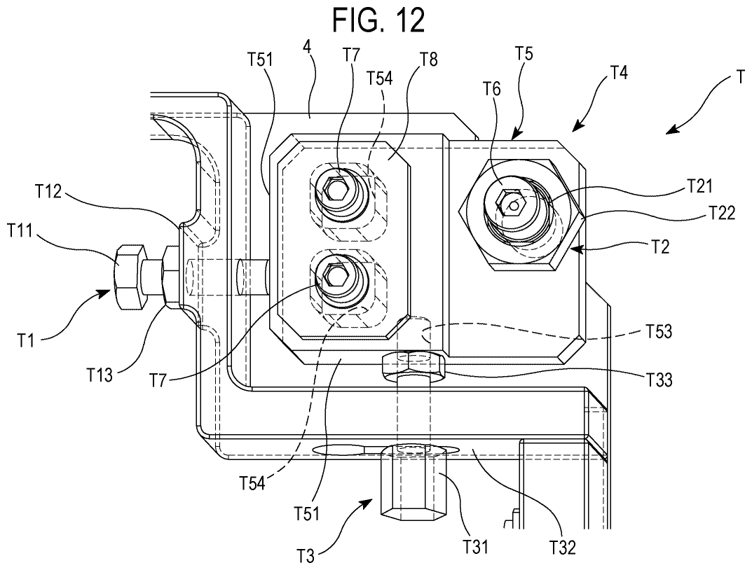

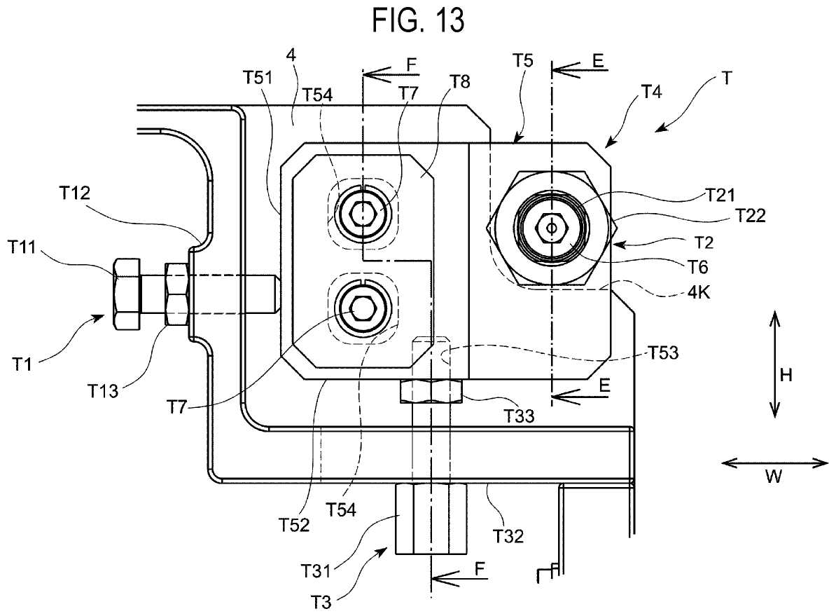

As shown in FIGS. 12 and 13, the X-axis movable body T11 is configured by using an X-axis jack bolt T11 arranged in a posture in which the axial direction of the X-axis jack bolt T11 coincides with the width direction W of the load port 1. When an operator applies an operation force to tighten the X-axis jack bolt T11, the X-axis jack bolt T11 is moved in a direction in which the tip end of the bolt is pressed against a side surface T51 of the load port guide part T5. The X-axis jack bolt T11 is held by the X-axis jack bolt stay T12 provided at a position facing the side surface T51 of the load port guide part T5 so as to be advanced and retreated. The X-axis jack bolt stay T12 is fixed to the base frame 4. In addition, the X-axis jack bolt stay T12 is provided with an X-axis nut T13 threadedly coupled to the X-axis jack bolt T11, and the position of the X-axis jack bolt T11 can be fixed by the X-axis nut T13.

The X-axis adjustment part T1 advances and retreats the X-axis movable body T11 in the width direction W of the load port 1, which makes it possible to move the entire load port 1 including the X-axis jack bolt stay T12 in the width direction W with respect to the load port guide part T5. In this embodiment, when a tightening operation force is applied to the X-axis movable body T11, the entire load port 1 including the X-axis jack bolt stay T12 is set to move in the width direction W away from the load port guide part T5 (specifically, the side surface T51).

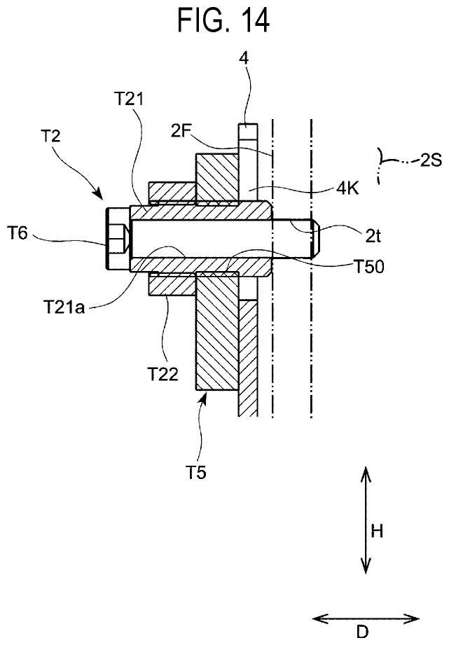

As shown in FIG. 14, the Y-axis movable body T21 is configured by using a Y-axis adjustment bolt T21 arranged in a posture in which the axial direction of the Y-axis adjustment bolt T21 coincides with the thickness direction D of the load port 1. When an operator applies an operation force to tighten the Y-axis adjustment bolt T21, the Y-axis adjustment bolt T21 is moved in a direction in which the tip end of the bolt is pressed against the wall surface (front wall surface 2F) of the transfer chamber 2. The Y-axis adjustment bolt T21 is held in the load port guide part T5 so as to be advanced and retreated. In the load port guide part T5, a screw hole T50 into which the Y-axis adjustment bolt T21 is threadedly coupled is formed to penetrate the load port guide part T5 in the thickness direction. In addition, a Y-axis nut T22 is provided at a position of the load port guide part T5 that overlaps with the screw hole T50 in the thickness direction D, and the Y-axis adjustment bolt T21 is threadedly coupled into the Y-axis nut T22 and the screw hole T50. By tightening the Y-axis nut T22, the movement of the Y-axis adjustment bolt T21 in the thickness direction D can be restricted, and the position of the Y-axis adjustment bolt T21 can be fixed. In this embodiment, a hollow cylindrical type bolt that penetrates in the axial direction is used as the Y-axis adjustment bolt T21, and a load port mounting bolt T6 is inserted into an axial hollow portion T21a of the Y-axis adjustment bolt T21. The total length of the load port mounting bolt T6 is longer than the total length of the Y-axis adjustment bolt T21. A tip end portion of the load port mounting bolt T6 can be inserted and threadedly coupled into the mounting hole 2t formed on the wall surface (front wall surface 2F) of the transfer chamber 2 either directly or via a nut (see FIG. 14). The head of the load port mounting bolt T6 is set to abut one end (front end) of the Y-axis adjustment bolt T21.

The Y-axis adjustment part T2 advances and retreats the Y-axis movable body T21 in the thickness direction D of the load port 1, which makes it possible to move the entire load port 1 in the thickness direction D (depth direction or tilt direction) with respect to the wall surface (front wall surface 2F) of the transfer chamber 2. In this embodiment, when a tightening operation force is applied to the Y-axis movable body T21, the entire load port 1 is set to move in the thickness direction D away from the wall surface (front wall surface 2F) of the transfer chamber 2.

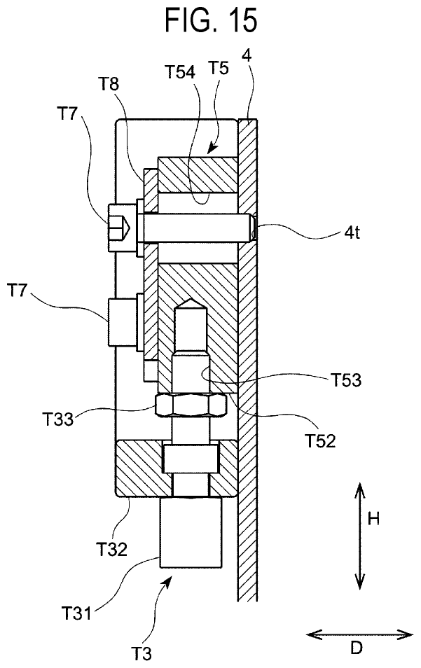

As shown in FIG. 15, the Z-axis movable body T31 is configured by using a Z-axis jack bolt T31 arranged in a position in which the axial direction of the Z-axis jack bolt T31 coincides with the height direction H of the load port 1. The Z-axis jack bolt T31 is held by a Z-axis jack bolt stay T32 provided at a position facing a downward facing surface T52 of the load port guide part T5 so as to be advanced and retreated. The Z-axis jack bolt stay T32 is fixed to the base frame 4. When an operator applies an operating force to tighten the Z-axis jack bolt T31, the Z-axis jack bolt T31 having a tip end (upper end) inserted into an insertion hole T53 formed on the downward facing surface T52 of the load port guide part T5 is moved upward. Then, a head of the Z-axis jack bolt T31 pushes the Z-axis jack bolt stay T32 upward. Thus, the entire base frame 4 to which the Z-axis jack bolt stay T32 is fixed, and eventually the entire load port 1 is moved upward. In addition, a Z-axis nut T33 that threadedly coupled to the Z-axis jack bolt T31 is provided on the downward facing surface T52 of the load port guide portion T5. The Z-axis nut T33 restricts the movement of the Z-axis jack bolt T31 in the height direction H, thereby fixing the position of the Z-axis jack bolt T31.

The Z-axis adjustment part T3 advances and retreats the Z-axis movable body T31 in the height direction H of the load port 1, thereby moving the entire load port 1 including the Z-axis jack bolt stay T32 in the height direction H with respect to the load port guide part T5. In this embodiment, when a tightening operation force is applied to the Z-axis movable body T31, the entire load port 1 including the Z-axis jack bolt stay T32 is set to move in the height direction H toward the load port guide part T5 (upward) as described above.

In this embodiment, the X-axis jack bolt stay T12 and the Z-axis jack bolt stay T32 are integrally formed and fixed to the base frame 4 (see FIGS. 12 and 13).

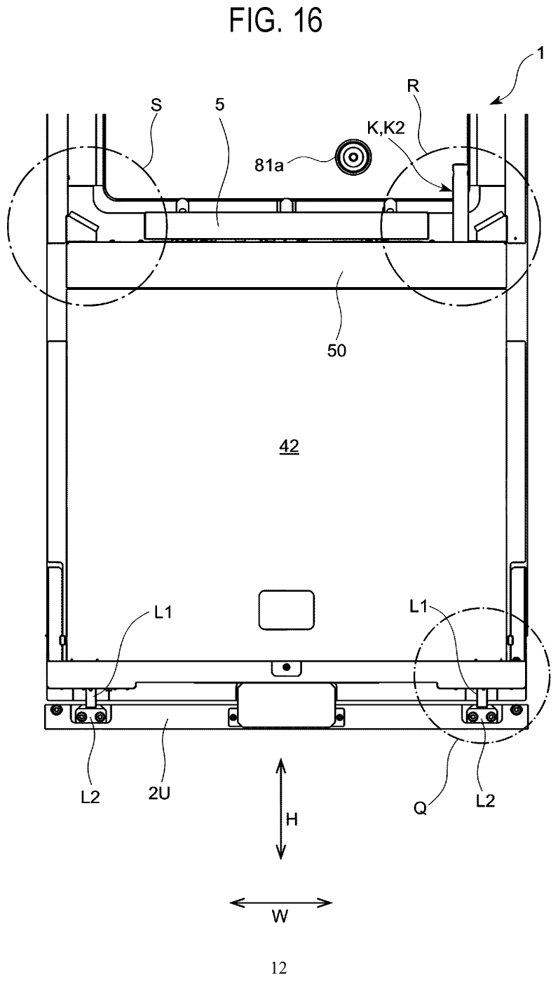

The load port guide part T5 is a plate-like part including the side surface T51 against which the tip end of the X-axis movable body T11 abuts and the downward facing surface T52 having the insertion hole T53 into which the Z-axis movable body T31 can be inserted. In this embodiment, as shown in FIG. 16, the load port guide part T5 having different thickness dimensions with the central portion in the width direction W used as a boundary is applied, and the portion against which the tip end of the X-axis movable body T11 abuts and the portion at which the insertion hole T53 is formed are set in the relatively thick portion. Furthermore, in the relatively thick portion of the load port guide part T5, there is formed a plate mounting bolt hole T54 into which the plate mounting bolt T7 for mounting the load port guide part T5 to the base frame 4 can be inserted. The plate mounting bolt hole T54 is set to a size that allows the plate mounting bolt T7 to be inserted with a sufficient play gap. In this embodiment, plate mounting bolt holes T54 are formed at a predetermined pitch in the height direction H at multiple locations (two locations in the illustrated example). In this embodiment, the load port guide part T5 can be fixed to the base frame 4 by inserting the plate mounting bolts T7 into the plate mounting bolt holes T54 while covering the plate mounting bolt holes T54 with the plate cover T8, and threadedly coupling the tip end of the plate mounting bolts T7 into the plate mounting bolt fixing holes 4t formed in the base frame 4.

As shown in FIG. 14, a threaded hole T50 into which the Y-axis adjustment bolt T21 threadedly coupled is formed in a relatively thin portion of the load port guide part T5. A predetermined region of the load port guide part T5 including the location where the threaded hole T50 is formed does not directly overlap the base frame 4 due to a notch 4K formed in the base frame 4, and faces the wall surface (front wall surface 2F) of the transfer chamber 2.

The load port mounting position adjustment mechanism T according to this embodiment includes, as a main element thereof, the three-axis adjustment mechanism T4 that combines the X-axis adjustment part T1, the Y-axis adjustment part T2, and the Z-axis adjustment part T3, and is arranged at both corners of the upper portion of the base frame 4. By going through the procedure described below at each arrangement location, it is possible to adjust the mounting position of the load port 1 with respect to the wall surface (front wall surface 2F) of the transfer chamber 2.

First, as preparation for the three-axis adjustment mechanism T4, the plate mounting bolt T7, the X-axis jack bolt T11 which is the X-axis movable body T11, and the Z-axis jack bolt T31 which is the Z-axis movable body T31 are loosened. The load port 1 in this preparation state is moved to a position close to the wall surface (front wall surface 2F) of the transfer chamber 2 with the base frame 4 kept in a vertical posture. Next, the load port mounting bolt T6 is inserted (or may be inserted in advance) into the axial hollow portion T21a of the Y-axis adjustment bolt T21, and the tip end portion of the load port mounting bolt T6 is inserted and threadedly coupled into the mounting hole 4t of the base frame 4 either directly or via a nut. It is important that the load port mounting bolt T6 is loosely fastened at this point, and the load port guide part T5 is allowed to move by about several mm in each of the width direction W (X-axis direction), the thickness direction D (Y-axis direction), and the height direction H (Z-axis direction) with respect to the base frame 4.

Next, the plate mounting bolts T7 are threadedly coupled and tightly fastened into the plate mounting bolt fixing holes 4t formed in the base frame 4. This makes it possible to fix the load port guide part T5 to the base frame 4. Next, the Y-axis mounting position adjustment process is performed by the Y-axis adjustment part T2. Specifically, when a tightening operation force is applied to the Y-axis adjustment bolt T21, the entire load port 1 is moved away from the wall surface (front wall surface 2F) of the transfer chamber 2, and when a loosening operation force is applied to the Y-axis adjustment bolt T21, the entire load port 1 is moved toward the wall surface (front wall surface 2F) of the transfer chamber 2. By appropriately applying such an operation force, the position of the entire load port 1 in the thickness direction D with respect to the wall surface (front wall surface 2F) of the transfer chamber 2 can be adjusted in units of several mm. In this embodiment, the position of the load port 1 at the initial setting time before the Y-axis adjustment process is set as a reference position, and the load port 1 is configured to be movable in the Y-axis direction (front-rear direction D) by a maximum of +2 mm (2 mm forward) from the reference position. After the position in the Y-axis direction has been adjusted, the position of the Y-axis adjustment bolt T21 is fixed by applying an operation force to tighten the Y-axis nut T22 provided on the load port guide part T5.

Next, the Z-axis mounting position adjustment process is performed by the Z-axis adjustment part T3. Specifically, when a tightening operation force is applied to the Z-axis jack bolt T31, the entire load port 1 including the Z-axis jack bolt stay T32 is moved upward with respect to the wall surface (front wall surface 2F) of the transfer chamber 2, and when a loosening operation force is applied to the Z-axis jack bolt T31, the entire load port 1 including the Z-axis jack bolt stay T32 is moved downward with respect to the wall surface (front wall surface 2F) of the transfer chamber 2. By appropriately applying such an operation force, the position of the entire load port 1 in the height direction H with respect to the wall surface (front wall surface 2F) of the transfer chamber 2 can be adjusted in units of several mm. In this embodiment, the position of the load port 1 after the Y-axis adjustment process is set as a Z-axis reference position, and the load port 1 is configured to be movable in the Z-axis direction (up-down direction H) within a range of +5 mm (within a range of 10 mm) from the Z-axis reference position. After the position in the Z-axis direction has been adjusted, the position of the Z-axis jack bolt T31 is fixed by applying an operation force to tighten the Z-axis nut T33 provided on the load port guide part T5.

Next, an X-axis mounting position adjustment process is performed by the X-axis adjustment part T1. Specifically, when a tightening operation force is applied to the X-axis jack bolt T11, the entire load port 1 including the X-axis jack bolt stay T12 is moved to one of the left and right sides (left side in the illustrated example) with respect to the load port guide part T5 temporarily fixed to the wall surface (front wall surface 2F) of the transfer chamber 2, and when a loosening operation force is applied to the X-axis jack bolt T11, the entire load port 1 is moved to the other of the left and right sides (right side in the illustrated example) with respect to the load port guide part T5. By appropriately applying such an operation force, the position of the entire load port 1 in the width direction W with respect to the wall surface (front wall surface 2F) of the transfer chamber 2 can be adjusted in units of several mm. In this embodiment, the position of the load port 1 after the Z-axis adjustment process is set as an X-axis reference position, and the load port 1 is configured to be movable in the X-axis direction (left-right direction) within a range of +5 mm (within a range of 10 mm) from the X-axis reference position. After the position in the X-axis direction has been adjusted, the position of the X-axis jack bolt T11 is fixed by applying an operation force to tighten the X-axis nut T13 provided on the X-axis jack bolt stay T12.

As described above, by sequentially performing the Y-axis mounting position adjustment process, the Z-axis mounting position adjustment process, and the X-axis mounting position adjustment process, it is possible to adjust the three-axis mounting positions of the entire load port 1 with respect to the wall surface (front wall surface 2F) of the transfer chamber 2. The order of the mounting position adjustment processes is not limited to the order of i) the Y-axis mounting position adjustment process, ii) the Z-axis mounting position adjustment process, and iii) the X-axis mounting position adjustment process, and may be performed in any appropriate order.

Finally, the load port mounting bolts T6, which are threadedly coupled into the mounting holes 2t on the wall surface (front wall surface 2F) of the transfer chamber 2 with a certain play gap (loose state), are firmly tightened. This makes it possible to maintain a state in which the load port guide part T5 and at least the vicinity of the region of the load port 1 where the load port guide part T5 is fixed do not move in any direction with respect to the wall surface (front wall surface 2F) of the transfer chamber 2.

In the load port mounting position adjustment mechanism T according to this embodiment, the three-axis adjustment mechanism T4 is provided at each of both ends of the upper section of the base frame 4, and each three-axis adjustment mechanism T4 is configured to be individually adjustable. Therefore, the operator is not forced to adjust the position of the load port 1 in the height direction H by accessing the jack bolt provided in a recessed position at the bottom of the base frame 4 in a crawling posture as in the related art, but is able to smoothly adjust the mounting position of the load port 1 by accessing the three-axis adjustment mechanism T4 in a standing posture. This makes it possible to improve the workability and shorten the mounting operation time. Moreover, the three-axis adjustment mechanism T4 can be mounted to the wall surface (front wall surface 2F) of the transfer chamber 2 by using the mounting holes 2t whose formation locations are specified by the SEMI standard on the wall surface (front wall surface 2F) of the transfer chamber 2. There is no need to provide dedicated mounting holes on the wall surface (front wall surface 2F) of the transfer chamber 2. The three-axis adjustment mechanism T4 can be easily placed and mounted on the wall surface (front wall surface 2F) of the existing transfer chamber 2, which also contributes to reducing the introduction cost.

Furthermore, according to the load port mounting position adjustment mechanism T of this embodiment, there is no need to arrange the height position adjustment jack bolt at the bottom of the base frame 4 in a posture in which the jack bolt protrudes downward further than the surrounding parts. Therefore, for example, when the load port 1 alone, or the entire EFEM including the load port 1 mounted to the transfer chamber 2 is moved by a forklift, there is no possibility that the forklift tines come into contact with or get caught on the exposed portion (lower end portion) of the height position adjustment jack bolt, thereby causing the forklift to tip over. This makes it possible to reduce safety risks.

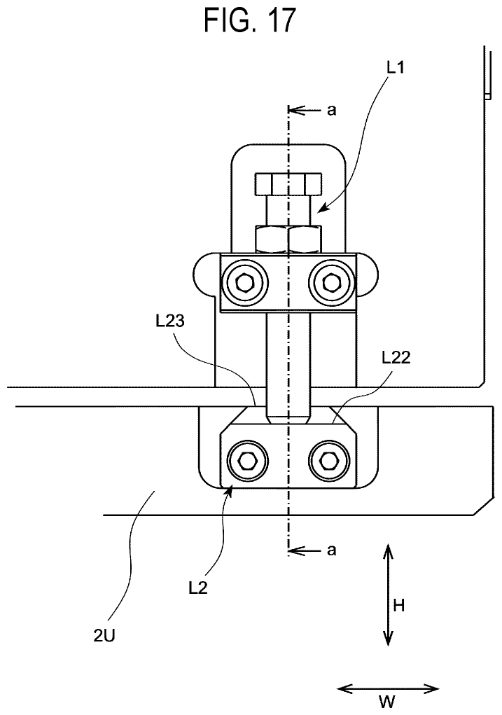

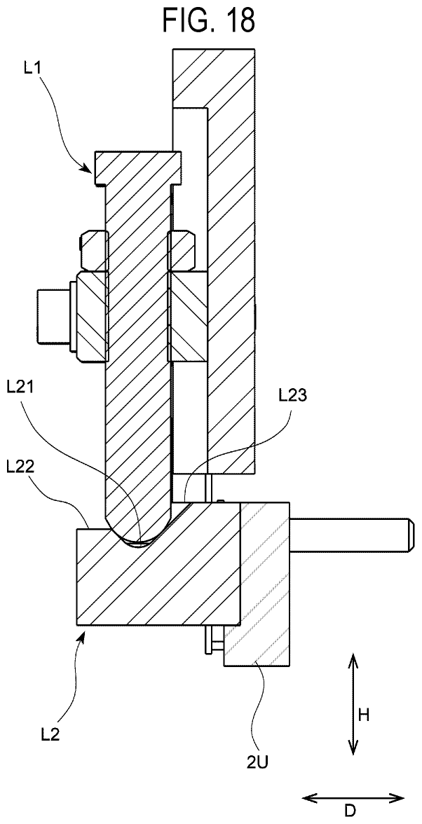

As shown in FIGS. 16 to 18, the load port mounting position adjustment mechanism T according to this embodiment includes the legs L1 provided at the bottom of the load port 1 and the leg receiving portions L2 provided on the lower portion of the wall surface (front wall surface 2F) of the transfer chamber 2. By placing the legs L1 on the leg receiving portions L2, the load port 1 can be mounted in a state that complies with the SEMI standard. In this regard, FIG. 16 is a front view of the lower half of the load port 1, FIG. 17 is an enlarged view of region Q in FIG. 16 with some parts removed, and FIG. 18 is a sectional view taken along line a-a in FIG. 17.

In this embodiment, as shown in FIG. 18, a block-shaped leg receiving portion L2 where a groove L21 into which a lower end portion of the leg L1 fit is formed continuously in the width direction W are applied. Although the jack bolts are exemplified as the legs L1 in FIG. 17 and FIG. 18, simple rod-shaped parts may also be used. Meanwhile, in this embodiment, as shown in FIG. 18, leg receiving portions in which the height of the upward facing surface is different in front and rear of the grooves L21 are used as the block-shaped leg receiving portions L2 that support the lower ends of such legs L1 in a state of being accommodated in the grooves L21. Specifically, the upward facing surface on the front side of the groove L21 (the front upward facing surface L22) is located at a lower position than the upward facing surface on the rear side of the groove L21 (the rear upward facing surface L23). Therefore, the depth from the front upward facing surface L22 to the bottom of the groove L21 is smaller than the depth from the rear upward facing surface L23 to the bottom of the groove L21.

The leg receiving portions L2 are fixed to a lower mounting bracket 2U which is fixed to the lower portion of the wall surface (front wall surface 2F) of the transfer chamber 2. In this embodiment, the legs L1 are provided at the lower end portions of the load port 1 on the left and right sides, and the leg receiving portions L2 are provided in the lower mounting bracket 2U at the positions corresponding to the legs L1.

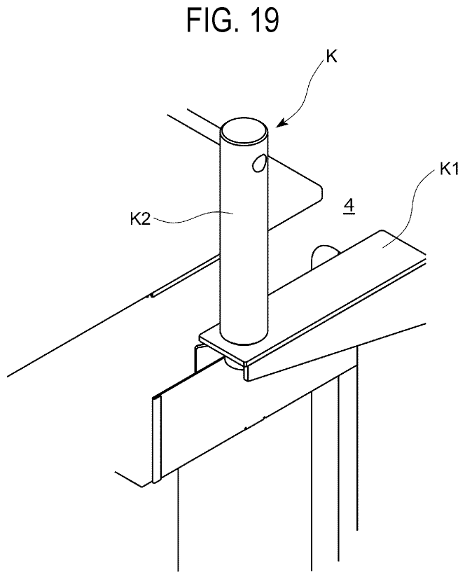

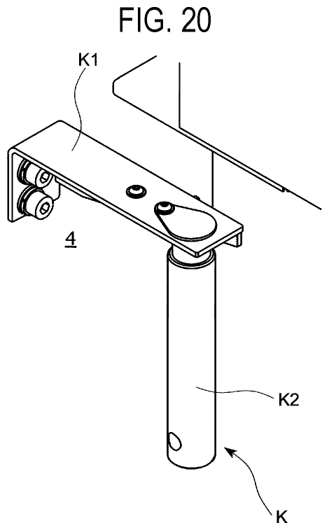

Furthermore, as shown in FIGS. 16, 19 and 20, the load port mounting position adjustment mechanism T according to this embodiment includes a handle K that can be grasped by an operator to apply a pressing force to move the entire load port 1 toward the wall surface (front wall surface 2F) of the transfer chamber 2 when mounting the load port 1 to the wall surface (front wall surface 2F) of the transfer chamber 2. In this regard, FIG. 19 is a perspective view of region R in FIG. 16 as seen from one side of the load port 1, and FIG. 20 is a perspective view of region S in FIG. 16 as seen from the other side of the load port 1. FIGS. 19 and 20 show a state in which some of the parts surrounding the handle K are removed.

The handle K includes a handle receiving portion K1 having a base end fixed to the base frame 4 and extending forward, and a rod-shaped handle main body K2 supported in an upright posture by the tip end portion of the handle receiving portion K1. The handle main body K2 is supported by the handle receiving portion K1 so as to be able to change its posture between a use posture (see FIG. 19) in which the handle main body K2 protrudes upward from the handle receiving portion K1 and a storage position (see FIG. 20) in which the handle main body K2 is stored in the internal space of the cover 50 (see FIG. 16) disposed below the handle receiving portion K1. In this embodiment, a pair of handles K is provided on the left and right sides of the base frame 4 at positions sandwiching the mounting table 5 in the width direction W.

With the load port mounting position adjustment mechanism T according to this embodiment, when mounting the load port 1 to the wall surface (front wall surface 2F) of the transfer chamber 2 by placing the legs L1 on the leg receiving portions L2, after the load port 1 has been moved by appropriate means from the front side (front) of the transfer chamber 2 to a position approaching the wall surface (front wall surface 2F), the operator grasps the handle main body K2 supported in the use posture by the handle receiving portion K1 and applies an operation force to push the handle main body K2 toward the wall surface (front wall surface 2F) of the transfer chamber 2. As a result, the entire load port 1 can be moved toward the wall surface (front wall surface 2F) of the transfer chamber 2, and the legs L1 provided at the bottom of the load port 1 can be placed on the leg receiving portions L2. At this time, by providing steps on the upward facing surfaces L22 and L23 of the leg receiving portions L2 and locating the front upward facing surface L22 at a lower position than the rear upward facing surface L23 with the groove L21 used as a boundary, the legs L1 can be smoothly placed on the leg receiving portions L2 by an operation of pushing the entire load port 1 to a position where the lower end portions of the legs L1 fit into the grooves L21 of the leg receiving portions L2 without having to temporarily tilt or lift the entire load port 1 in order to place the legs L1 on the leg receiving portions L2. At an appropriate timing after the legs L1 have been placed on the leg receiving portions L2, the posture of the handle main body K2 is changed from the use position (see FIG. 19) to the storage position (see FIG. 20). Therefore, the handle main body K2 can be stored in the internal space of the cover 50, thereby preventing the handle K from interfering with other parts after the load port mounting operation.

As described above, with the load port mounting position adjustment mechanism T according to this embodiment, the upward facing surface L22 in front of the leg receiving grooves L21 formed on the upper surface of the block-shaped leg receiving portion L2 is located at a lower position than the upward facing surface L23 behind the leg receiving groove L21 with the leg receiving groove L21 formed on the upper surface of the block-shaped leg receiving portion L2 used as a boundary. Therefore, when an operator wants to mount the load port 1 to the wall surface (front wall surface 2F) of the transfer chamber 2, the operator applies an operation force to push the load port 1 toward the wall surface (front wall surface 2F) of the transfer chamber 2, whereby the leg L1 fits smoothly into the leg receiving groove L21 through the upward facing surface L22 in front of the leg receiving groove L21. The leg L1 abuts the portion of the leg receiving portion L2 behind the leg receiving groove L21, so that the leg L1 can be prevented from moving further toward the wall surface (front wall surface 2F) of the transfer chamber 2 and can be kept fitted into the leg receiving groove L21. Therefore, even with a large and heavy load port 1 developed to be compatible with large wafers (large substrates), it is possible to avoid risks (such as the load port 1 tipping over) that would otherwise be caused by having to tilt the entire load port when mounting the load port to the wall surface (front wall surface 2F) of the transfer chamber 2. In addition, by specifying the location where the leg receiving portions L2 receive (support) the legs L1, it is possible to clarify the operation location of the load port 1 during mounting, which has been unclear in the related art, and the mounting operation can be easily carried out by any operator.

In particular, the load port mounting position adjustment mechanism T according to this embodiment includes the handle K extending horizontally from the base frame 4 within the reach of the operator. Therefore, even if the load port 1 is provided with a large mounting table 5 capable of loading large FOUPs for storing wafers which are becoming larger, and particularly, even if the load port 1 is so large and heavy that an operator cannot reach the base frame 4 by stretching his/her hand from the tip end (tip end) side of the mounting table 5, the operator can grasp the handle K and can apply an operation force to push the load port 1 toward the wall surface (front wall surface 2F) of the transfer chamber 2, and the operator can smoothly and appropriately perform the mounting operation on the wall surface (front wall surface 2F) of the transfer chamber 2.

The present disclosure is not limited to the above-described embodiment. For example, in the above-described embodiment, the X-axis adjustment part, the Y-axis adjustment part, and the Z-axis adjustment part are configured to use the thread coupling and the advance/retreat movement of the bolt. However, the type of bolt is not particularly limited. It may be possible to adopt a configuration that uses the advance/retreat movement of a part other than the bolt.

In addition, the three-axis adjustment mechanism may be mounted to the wall surface of the transfer chamber by using the mounting holes (the holes designated by reference symbols 2t (2c) in FIG. 3) formed in the middle portion of the wall surface of the transfer chamber. As described above, the SEMI standard requires that the mounting holes be formed at predetermined locations on the upper, middle, and lower sections of the wall surface of the transfer chamber. The position adjustment mechanism according to the present disclosure can be mounted to the wall surface of the transfer chamber by using the upper and middle holes as specified by the SEMI standard.

The transfer container is not limited to the FOUP, and may be a container other than the FOUP, such as a front opening shipping box (FOSB) or a cassette.

As described above, the load port according to the present disclosure can be used as a part of the EFEM. However, the load port may also be applied to transfer devices other than the EFEM. In such a case, the mounting position adjustment mechanism according to the present disclosure can be applied to facilitate the mounting of the load port in the transfer chamber.

In the above-described embodiment, a wafer is used as an example of the transfer target object. However, the transfer target object may also be a reticle, a rectangular substrate including a liquid crystal transfer target object or a glass transfer target object, a ring frame wafer, a culture plate, a culture container, a dish, a petri dish, or the like.

Furthermore, the specific configuration of each part is not limited to the above-described embodiment, and various modifications may be made without departing from the spirit of the present disclosure.

### EXPLANATION OF REFERENCE NUMERALS

1: load port, 2: transfer chamber, 2t: mounting hole, T: load port mounting position adjustment mechanism, T1: X-axis adjustment part, T2: Y-axis adjustment part, T3: Z-axis adjustment part, T4: 3-axis adjustment mechanism, L1: leg, L2: leg receiving portion, K: handle, K2: handle main body

1. A load port mounting position adjustment mechanism capable of adjusting a mounting position of a load port on a wall surface of a transfer chamber that defines a substantially closed substrate transfer space in the transfer chamber, the load port mounting position adjustment mechanism comprising:
an X-axis adjustment part configured to adjust a position of the load port in a width direction of the wall surface;
a Y-axis adjustment part configured to adjust the position of the load port in a thickness direction of the wall surface; and
a Z-axis adjustment part configured to adjust the position of the load port in a height direction of the wall surface,
wherein a three-axis adjustment mechanism that integrates the X-axis adjustment part, the Y-axis adjustment part and the Z-axis adjustment part is mounted to the wall surface by using a mounting hole formed in at least one of an upper section or a middle section of the wall surface.

2. The load port mounting position adjustment mechanism of claim 1, further comprising:
a leg provided at a lower end portion of a base frame; and
a leg receiving portion provided at a lower end of the wall surface to support the leg,
wherein the leg receiving portion includes a groove into which a lower end of the leg is fitted and an upward facing surface,
wherein a front portion of the upward facing surface is a portion farther from the wall surface than the groove with the groove used as a boundary, and is set at a lower position than an a rear portion of the upward facing surface, which is a portion closer to the wall surface than the groove.

3. The load port mounting position adjustment mechanism of claim 2, further comprising:
a handle having a handle main body disposed at a position spaced apart from the wall surface of the transfer chamber by a predetermined distance,
wherein an operator is capable of accessing the handle main body at least when mounting the load port to the wall surface.

4. The load port mounting position adjustment mechanism of claim 1, further comprising:
a handle having a handle main body disposed at a position spaced apart from the wall surface of the transfer chamber by a predetermined distance,
wherein an operator is capable of accessing the handle main body at least when mounting the load port to the wall surface.
